(19) United States
(12) Patent Application Publication
(10) Pub. No.: US 2003/0015758 A1
(43) Pub. Date: Jan. 23, 2003

(54) Semiconductor device and method therefor

(76) Inventors: William J. Taylor, JR, Round Rock, TX (US); Bich-Yen Nguyen, Austin, TX (US); David L. O'Meara, Poughkeepsie, NY (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 09/910,370

(22) Filed: Jul. 21, 2001

(51) Int. Cl. H01L 29/76; H01L 21/3205

(52) U.S. Cl. 257/368; 438/585; 257/413

(57) ABSTRACT

A semiconductor device has a semiconductor region that functions as a channel between two metal conductors. In the semiconductor region and adjacent to the metal conductors are doped regions of an opposite conductivity type to that of the channel that are source and drain regions, which are electrically coupled laterally to the two metal conductors and function as ohmic contacts. The semiconductor region is epitaxially grown through a hole in an insulating layer that underlies the two metal conductors. Under the insulating layer is a semiconductor layer that forms the seed for epitaxially growing the semiconductor layer. The hole is also formed through another relatively thick insulating layer over the two metal conductors.

### FIELD OF THE INVENTION

The field of the invention generally relates to a semiconductor device and more particularly to a transistor with high-conductivity source and drain regions.

### BACKGROUND

In transistor structures where the source and drain are formed by doping the semiconductor substrate there exists a series of resistances that can adversely affect the performance of the transistor. There is a first resistance within the channel underneath the gate electrode and a second resistance between the channel region and the extension. A third resistance exists within the extension itself and a fourth resistance is in the source/drain region. If a silicide region is formed to serve as a contact to the source/drain region, there also will be a resistance between the silicide and the source/drain region. There is a desire to decrease the sum total of the resistances in order to increase performance of the transistor. One way of achieving this is by forming a deeper source/drain region or deeper extension regions. This will decrease the resistances of the source/drain region and the extension, respectively. One problem with this approach is that the deeper regions are too far away from the gate electrode for the gate electrode to control the carriers in the well and channel regions as well as desired. This can lead to leakage and to a change in the threshold to voltage of the device. Another way to decrease the resistance of the third, fourth and fifth resistances is by increasing the doping. In current technology, however, the doping is already so high that it has reached the solubility limit of the semiconductor material. Thus, increasing the doping is no longer an option. Therefore, a need exists to find a way to decrease the resistance of the transistor.

### BRIEF DESCRIPTION OF THE DRAWINGS

The present invention is illustrated by way of example and not limited by the accompanying figures, in which like references indicate similar elements, and in which:

FIG. 1 illustrates a portion of a substrate in accordance with an embodiment of the present invention.

FIG. 2 illustrates the substrate of FIG. 1 after etching an opening;

FIG. 3 illustrates the substrate of FIG. 2 after forming an epitaxial region;

FIG. 4 illustrates the substrate of FIG. 3 after forming a gate insulator and depositing a gate electrode layer;

FIG. 5 illustrates the substrate of FIG. 4 after forming a gate electrode and ruing ion implantation;

FIG. 6 illustrates the substrate of FIG. 5 after heating;

FIG. 7 illustrates the substrate of FIG. 6 after forming a silicide layer; and

FIG. 8 illustrates the substrate of FIG. 7 after forming an interlevel dielectric layer and vias.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention. More specifically, the source and drain regions 14 can be any desired length.

### DETAILED DESCRIPTION OF THE DRAWING

Doped semiconductor source and drain regions are replaced by low resistivity metal regions so that the resistance in the extension region and in the source and drain regions is decreased. The resistance that exists between the channel and the extension is also changed. Since the extension region is doped by diffusing dopants into the extension region, the resulting diffused profile is believed to be more abrupt than an implanted profile that may or may not be subsequently annealed and thereby reduces resistance.

Shown in FIG. 1 is a device structure 8 comprising a substrate 10, a dielectric layer 12, a metal layer 14, an etch stop layer (ESL) 16, a sacrificial layer 18 and a photoresist layer 20. The substrate 10 has a semiconductor layer such as silicon, gallium arsenide, silicon germanium, and the like, and may include an insulator such as in silicon on insulator (SOI). In a preferred embodiment, substrate 10 is monocrystalline. Dielectric layer 12, which is a thick insulator, is formed over the substrate 10 by chemical vapor deposition (CVD), physical vapor deposition (PVD), or the like, or combinations of the above. In one embodiment, the dielectric layer 12 is at least 10 times thicker than the subsequently formed metal layer 14. In one embodiment, the dielectric layer 12 is about 3000 Angstroms and is silicon dioxide deposited using tetraorthosilane (TEOS). Other dielectric materials may be used. The metal layer 14 is formed using CVD, PVD, atomic layer deposition (ALD), the like, or combinations of the above, over the dielectric layer 12. In one embodiment, the metal layer 14 is formed over an optional thin buffer or adhesion layer, which can be amorphous. The material(s) chosen for the metal layer 14 should not kill the lifetime of the minority carriers in the semiconductor material used for the substrate 10. The metal layer may include nitrogen (such as titanium nitride and tantalum nitride), a refractory metal, silicon, or any other suitable material. In another embodiment, two different types of metal are deposited to form metal layer 14, which would require an additional patterning process. In this embodiment, the subsequent tapered etch may be performed such that the metal layers 14 on either side of the opening are different. Alternately, the two different metals can be deposited so that the NMOS transistors include a first metal layer and PMOS transistors include a different metal layer.

Etch stop layer (ESL) 16 is formed by CVD, PVD, ALD, the like, or combinations of the above. In one embodiment the ESL 16 is a nitride such as the silicon nitride. The ESL 16 can be approximately 100-500 angstroms or more specifically, approximately 200 angstroms. The metal layer 14 is generally approximately 100-300 Angstroms and preferably, thicker than the metal layer 14. Sacrificial layer 18 may be formed by CVD, PVD and the like, may be approximately 3000 Angstroms, and may be an oxide and, more specifically, a silicon dioxide formed using TEOS. A photoresist layer 20 is formed and patterned over the sacrificial layer 18 as shown in FIG. 1.

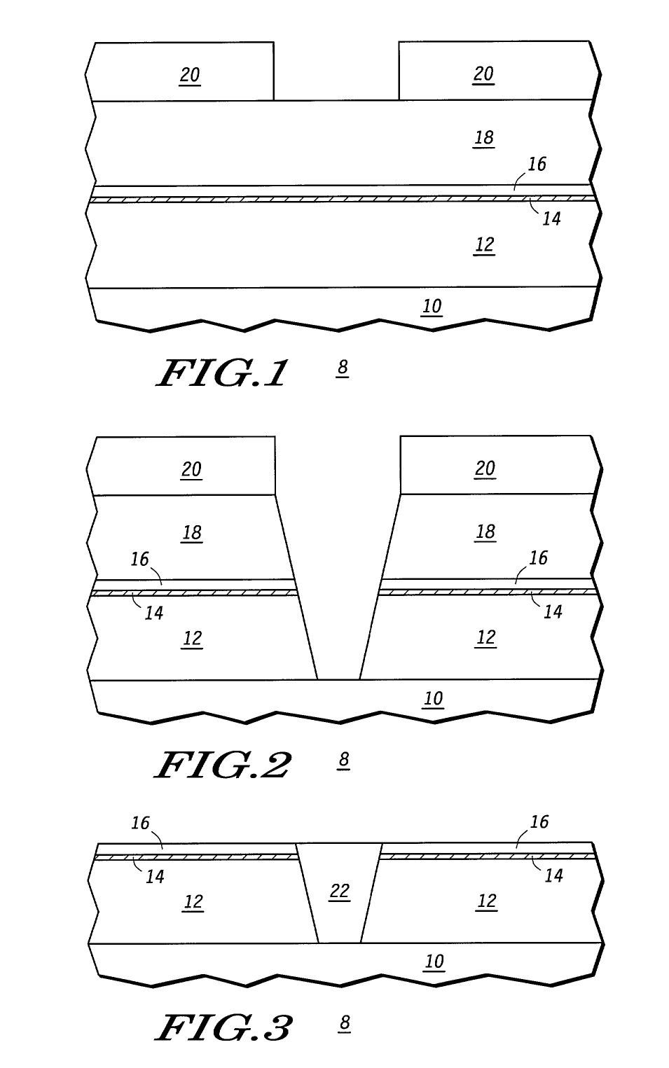

Shown in FIG. 2 is the device structure 8 after a tapered etch is performed as is shown in FIG. 2. The etch profile is tapered from the junction of the photoresist layer 20 and the sacrificial layer 18 down to the surface of the substrate 10. The angle between sidewalls 21 and the surface of the substrate 10 is less than 90 degrees and will generally be approximately 80-60 degrees. In order to obtain this tapered etch, an etch process utilizing a carbon and fluorine containing gas along with oxygen can be used to etch the sacrificial layer 18 and the dielectric layer 12. A fluorine-containing chemistry can be used to etch the ESL 16 and a chlorine-containing chemistry can be used to etch the metal layer 14. The introduction of oxygen with the carbon and fluorine containing gas results in a resist erosion that facilitates the formation of the tapered etch profile. Specific gases that can be used include CHF₃, CF₄, C₂F₆, C₃F₈, and C₄F₈. The resulting structure has two etch stop layers 16 formed over the two metal regions 14. The semiconductor substrate 10, which is a semiconductor layer, is exposed after etching the hole.

After the tapered etch, the photoresist layer 20 is removed. Preferably, the sacrificial layer 18 is also removed after forming the tapered etch profile. If sacrificial layer 18 is silicon dioxide, an HF dip can be performed to remove the layer. Next, an epitaxial region 22 is formed in contact with the substrate 10. Single or compound semiconductor materials that may be doped or undoped form the epitaxial region 22. For example, in specific embodiments, the epitaxial region 22 can include silicon, gallium nitride, gallium arsenide, indium gallium arsenide and indium phosphide. The epitaxial region 22 or semiconductor region 22 will have substantially the same single crystalline semiconductor structure as the underlying substrate 10. For example, the epitaxial region 22 will have essentially the same orientations as the underlying substrate 10. Thus, if the substrate 10 is monocrystalline, the epitaxial region 22 will also be monocrystalline. In one embodiment, the epitaxial region 22 is disposed between two metal layers having a top surface at a height above the bottom surfaces of the metal layers and lower than 100 Angstroms above a first plane, which is the top surface of the metal layers.

In accordance with a specific embodiment, the epitaxial region 22 can be grown with or without a dopant. In a preferred embodiment, epitaxial region 22 is undoped. In another embodiment, epitaxial region 22 is doped to a level that is less than the subsequently formed extension regions. In general, a doping concentration less than ten to the eighteenth atoms per centimeter cubed may be used. In one embodiment, there is a concentration gradient of an element, such as germanium, which increases from the substrate, which is also the bottom of the epitaxial region 22, to the top of the epitaxial region 22 or the metal layer 14.

Preferably, the epitaxial region 22 is grown so that the top surface is above the top surface of ESL 16. In this case, facets will be seen at the top corners of the epitaxial region 22. Afterwards, the epitaxial region 22 is made substantially planar to the ESL 16 by an etch back. In one embodiment, the etch back is a chemical mechanical polishing process. In another embodiment, the epitaxial region 22 is grown at least up to the metal layer 14. Optionally, the epitaxial region 22 can be grown before removal of the sacrificial layer 18. In this case, the epitaxial silicon region is grown to a thickness that is above the top surface of the ESL 16 and the sacrificial layer 18, and a portion of the epitaxial region that is above the top surface of the ESL 16 are removed. This can be done by an etch back, such as a chemical mechanical process. It is preferred to grow the epitaxial region 22 above the top surface of the ESL 16 and then perform an etch back, because the etch back will remove defects that may have been formed. Therefore, the defects are minimized in the epitaxial region 22 when an etch back is used.

In an alternate embodiment, the epitaxial region 22 can be grown to a thickness that is below the top surface of the ESL 16 and above the bottom surface of the metal layer 14. In this embodiment, a chemical mechanical polishing process is not necessary. Shown in FIG. 3 is the device structure after formation of the epitaxial region 22, regardless of the embodiment used.

Although only one transistor is shown, substrate 10 will have many transistors formed simultaneously. Therefore, it is necessary to electrically separate the source and drain regions 14 of the transistors in order to prevent shorting. This process can be performed following the growth of the epitaxial region 22. A second photoresist layer (not shown) is formed and patterned. Portions of the ESL 16 and the metal layer 14 are etched. The same chemistry that was used to previously remove portions of the ESL 16 and the metal layer 14 can be used. The resulting openings will later be filled with a dielectric material during formation of an interlevel dielectric (ILD) layer, as described below.

Since the top surface of the epitaxial region 22 and all embodiments described results in a rough surface, a sacrificial oxide is grown over the epitaxial region 22 and removed. In a preferred embodiment, the epitaxial region 22 is silicon and the sacrificial oxide is SiO₂. Since the thermally grown SiO₂ will consume a portion of the epitaxial region 22 during formation, the sacrificial oxide is grown to a thickness so that the top surface of the epitaxial region 22 is substantially coplanar with the top of the metal layer 14. Afterwards, the sacrificial oxide is removed. If the sacrificial oxide is SiO2, an HF chemistry may be used.

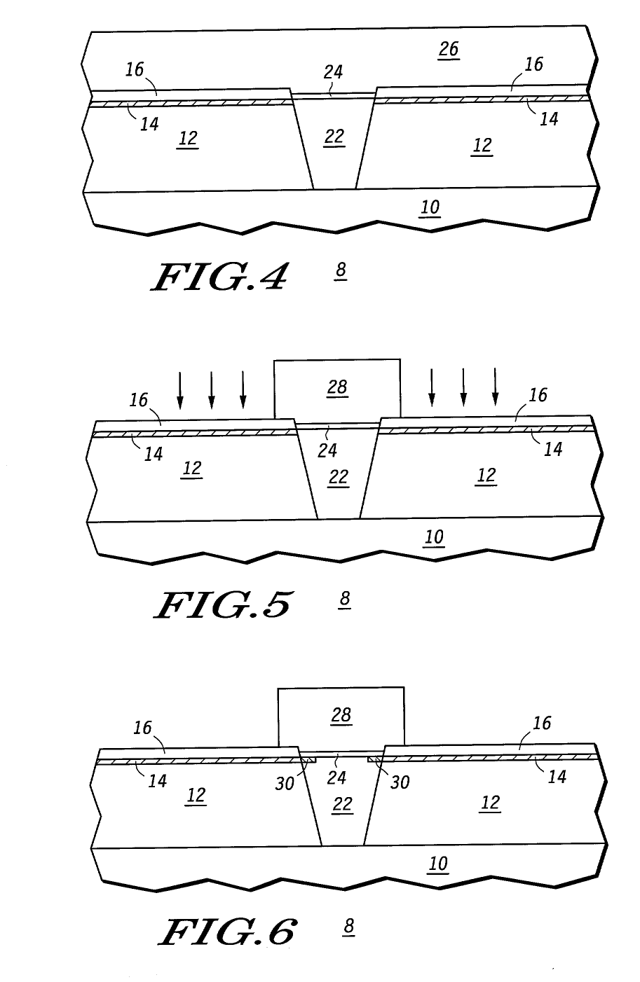

Shown in FIG. 4 is a gate insulator 24 formed over the epitaxial region 22. In a preferred embodiment the gate insulator 24 is a metal oxide such as hafnium oxide or zirconium oxide, and is formed by CVD, PVD, ALD, the like, or combinations of the above. The thickness of the gate insulator 24 if it is a metal oxide is approximately 10-100 Angstroms. In another embodiment the gate insulators 16 include nitrides, such as silicon nitride.

In another embodiment, the gate insulator 24, is a silicon dioxide layer of approximately 5 to 50 Angstroms. Generally, the silicon dioxide layer is formed by thermal growth. In one embodiment, the bottom surface of the gate insulator 24 is within approximately 100 Angstroms of the top surface of the metal layer 14 as shown in FIG. 4. In this embodiment, the subsequently formed extension regions 30 will not be in direct contact with the gate insulator 24 and may allow for decreased capacitance between the subsequently formed gate electrode 28 and the source and drain regions 14. This decreased capacitance should improve transistor performance. In another embodiment, each metal layer 14 has a top surface along a first plane and a bottom surface along the second plane. The epitaxial region 22 has a top surface at a height above the second plane and lower than 100 Angstroms above the first plane.

After forming the gate insulator 24, a gate electrode layer 26 is deposited. In a preferred embodiment, gate electrode layer 26 is polysilicon. In another embodiment the gate electrode layer 26 includes a metal. The gate electrode layer 26 is then patterned and etched to form a gate electrode 28 as shown in FIG. 5. In the resulting structure the gate electrode extends over portions of both ESL16.

Shown in FIG. 5 is device structure 8 after an ion implantation is performed to implant dopants into the metal layer 14 through the ESL 16 so that the metal layer 14 serves as a source and drain regions. Generally, a dose of approximately 5×10¹⁵ atoms per centimeter squared is used. Afterwards, an anneal of the metal layer 14 is performed at a temperature between approximately 700-900 degrees Celsius. Although this anneal is not required, it is performed in the preferred embodiment in order to convert what would be a Schottky contact without an anneal to an Ohmic contact. Ohmic contacts are more advantageous than Schottky contacts since the ohmic contact decreases the resistance.

Shown in FIG. 6 is the device structure 8 after the anneal. The resulting structure is an epitaxial region 22 with a center portion of a first conductivity type with two extension regions 30, which are also referred to as side portions that are a second conductivity type. The extension regions 30 lie within the epitaxial region 22 under the gate insulator 24 and adjacent to the source and drain regions 14. Thus, in one embodiment a monocrystalline semiconductor region has a center region of a first conductivity type, a first portion on a first side of a second conductivity type and a second portion on a second side of the second conductivity type. In another embodiment, the epitaxial region 22 also has a center portion of a first conductivity type, a first side portion adjacent to the first metal layer of a second conductivity type and a second side portion adjacent to the second metal layer of the second conductivity type.

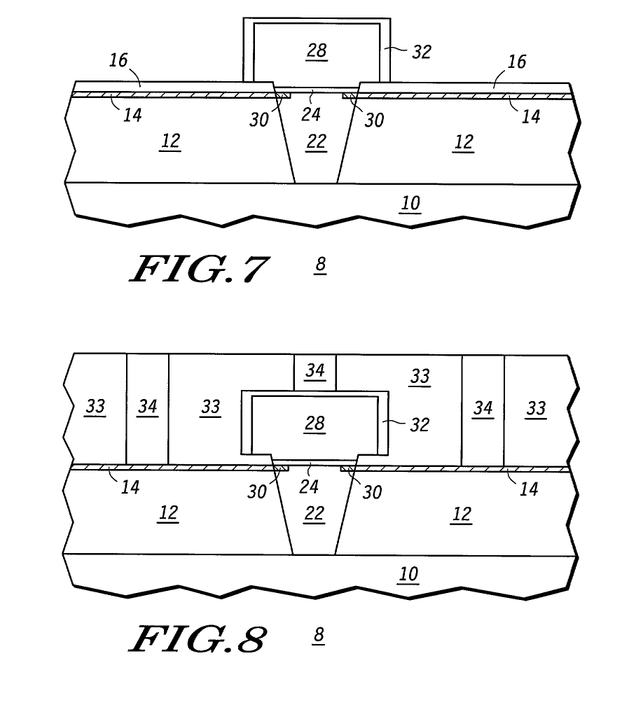

Shown in FIG. 7 is the device structure 8 after a the silicide layer 32 is formed around the gate electrode 28. To form the silicide layer 32, a metal such as titanium is deposited using CVD, PVD or other like at a temperature of approximately less than 400 degrees Celsius and at a thickness of approximately 100 Angstroms. The structure is then heated at a temperature within approximately 400-800 degrees Celsius in order for the titanium to react with a silicon in the gate electrode 28. Portions of the substrate 10 that do not have a top surface including silicon will not react with the titanium to form a silicide layer, hence, the titanium over these portions can be sequentially etched and removed. Next, the ESL 16 is optionally removed by using an anisotropic chemistry such as a wet etch. As can be appreciated by a skilled artisan, the ESL 16 also served as an offset liner layer by substantially separating the gate electrode 28 (and silicide layer 32) from the metal layer 14. This separation decreases or eliminates the capacitance between the gate electrode 28 and the metal layer 14.

Shown in FIG. 8 is the device structure 8 after an ILD 33 is formed by CVD, PVD, ALD, the like or combinations of the above, and patterned to form via openings over the source region, drain region, and in contact with the silicide layer 32 over the gate electrode 28 to form a semiconductor device or transistor, as shown in FIG. 8. As previously discussed, the dielectric material will fill the openings formed to isolate the source and drain regions of various transistors (not shown). The via openings are filled with a conductive material, such as copper, to form vias 34. Alternately, a dual inlaid or trench first process can be performed as is known to one of ordinary skill in the art.

The resulting structure advantageously decreases the overall resistance of the transistors and substantially decreases the capacitance between the source/drains regions and the well region, thereby improving transistor performance. Additionally, the method of forming the resulting structure allows for the formation of sub-lithographic gate lengths. As can be appreciated by a skilled artisan, the method of forming the resulting structure eliminates processing steps such as spacer formation and formation of wells. The elimination of steps may result in a net reduction of processing time.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A semiconductor device comprising:
a first metal layer having a top surface along a first plane and a bottom surface along a second plane;
a second metal layer having a top surface along the first plane and a bottom surface along the second plane;
a semiconductor region, disposed between the first metal layer and the second metal layer, having a top surface at a height above the second plane and lower than 100 Angstroms above the first plane, a center portion of a first conductivity type, a first side portion adjacent to the first metal layer of a second conductivity type, and a second side portion adjacent to the second metal layer of the second conductivity type;
a gate insulator over the semiconductor region; and
a gate electrode over the gate insulator.

2. The semiconductor device of claim 1, further comprising:
a first insulator over the first metal layer; and
a second insulator over the second metal layer.

3. The semiconductor device of claim 2, wherein the gate electrode is further characterized as extending over a first portion of the first insulator and a first portion of the second insulator.

4. The semiconductor device of claim 3, wherein the first insulator and the second insulator comprise nitride.

5. The semiconductor device of claim 2 further comprising:
a thick insulator under the first and second metal layers and around the semiconductor region; and
a semiconductor layer under the thick insulator and the semiconductor layer in contact with the semiconductor region.

6. The semiconductor device of claim 5, wherein the semiconductor region and the semiconductor layer are monocrystalline.

7. The semiconductor device of claim 6, wherein the semiconductor region has a germanium concentration that increases from the semiconductor layer to the top surface of the semiconductor region.

8. The semiconductor device of claim 7, wherein the gate insulator is a metal oxide.

9. The semiconductor device of claim 6, wherein the semiconductor region comprises silicon.

10. The semiconductor device of claim 1, wherein the first and second metal layers comprise a refractory metal.

11. The semiconductor device of claim 1, wherein the first and second metal layers are different types of metal.

12. A transistor, comprising:
a monocrystalline semiconductor region having a center region of a first conductivity type, a first portion on a first side of a second conductivity type, and a second portion on a second side of the second conductivity type;
a first metal region on the first side of the monocrystalline semiconductor region;
a second metal region on the second side of the monocrystalline semiconductor region;
a gate insulator over the monocrystalline semiconductor region; and
a gate electrode over the gate insulator.

13. The transistor of claim 12, wherein the first and second metal regions comprise a refractory metal.

14. The transistor of claim 13, wherein the first and second metal regions further comprise nitrogen.

15. The transistor of claim 13, wherein the first and second metal regions further comprise silicon.

16. The transistor of claim 12 further comprising:
a thick insulator under the first and second metal regions and around the monocrystalline semiconductor region; and
a semiconductor layer under the thick insulator and the monocrystalline semiconductor region in contact with the monocrystalline semiconductor region.

17. The transistor of claim 16, wherein the first and second metal regions have a first thickness and the thick insulator has a second thickness that is at least ten times thicker than the first thickness.

18. A method of making a semiconductor device comprising the steps of:
providing a structure comprising a semiconductor layer of a first conductivity type, a first insulating layer over the semiconductor layer, and a metal layer over the first insulating layer;
etching a hole through the first insulating layer and the metal layer to expose the semiconductor layer;
epitaxially growing a semiconductor region in the hole at least up to the metal layer;
patterning the metal layer to leave a first metal region and a second metal region adjacent to the hole;
forming an insulating region over the semiconductor region; and
forming a conducting region over the insulating region.

19. The method of claim 18, further comprising:
implanting dopants for forming a second conductivity type into the first and second metal regions; and
heating the dopants, after epitaxially growing the semiconductor region, to cause them to diffuse into the semiconductor region to cause first and second regions of the second conductivity in the semiconductor region.

20. The method of claim 19, further comprising etching back the semiconductor region prior to implanting the dopants.

21. The method of claim 20, wherein etching back comprises using chemical mechanical polishing.

22. The method of claim 21, wherein the structure is further characterized as having a second insulating layer over the metal layer and a third insulating layer over the second insulating layer and etching the hole is further characterized as etching through the second insulating layer and the third insulating layer.

23. The method of claim 22 further comprising removing the third insulating layer after etching the hole.

24. The method of claim 18, wherein the semiconductor region comprises germanium.

25. The method of claim 24, wherein the semiconductor region has a germanium concentration that increases from the semiconductor layer to the metal layer.
